(19) United States
(12) Patent Application Publication
(10) Pub. No.: US 2026/0338641 A1
(43) Pub. Date: Oct. 29, 2026

(54) SELF-DRIVING MOTORCADE HARDWARE-IN-THE-LOOP DYNAMIC TESTING SYSTEM AND METHOD

(71) Applicant: TSINGHUA UNIVERSITY, Beijing (CN)

(72) Inventors: Ruihai MA, Beijing (CN); Junzhi ZHANG, Beijing (CN); Chengkun HE, Beijing (CN); Weilong LIU, Beijing (CN)

(73) Assignee: TSINGHUA UNIVERSITY, Beijing (CN)

(21) Appl. No.: 19/115,268

(22) PCT Filed: Sep. 26, 2022
(86) PCT No.: PCT/CN2022/121257

§ 371 Date: Mar. 26, 2025

(51) Int. Cl. G01M 17/007; G06F 30/20; H04W 4/46

(52) U.S. Cl. CPC G01M 17/007; G06F 30/20; H04W 4/46

(57) ABSTRACT

A self-driving motorcade hardware-in-the-loop dynamic testing system includes: a head vehicle control apparatus configured to provide a head vehicle operation instruction; a motorcade real-time motion calculation apparatus, configured to perform online calculation of the dynamic and kinematic state parameters of a head vehicle and a following vehicle in the self-driving motorcade based on the head vehicle operation instruction; a motorcade scenery apparatus, configured to acquire the head vehicle operation instruction and the dynamic and kinematic state parameters of the head vehicle and the following vehicle, and display a motorcade operation scene; a dynamic test bench, configured to simulate actual operation states of the head vehicle and the following vehicle, and test the drive braking operation of the electric drive braking system of each vehicle; and a motorcade dynamic test bench loading calculation apparatus, configured to dynamically load the electric drive braking system of each vehicle in real-time.

### CROSS-REFERENCE TO THE RELATED APPLICATIONS

This application is the national phase entry of International Application No. PCT/CN 2022/121257, filed on Sep. 26, 2022, the entire contents of which are incorporated herein by reference.

### TECHNICAL FIELD

The present invention relates to a self-driving motorcade hardware-in-the-loop dynamic testing system and method, and relates to the technical field of vehicle test.

### BACKGROUND

Self-driving motorcade is an effective way to ensure traffic safety, improve traffic efficiency and realize energy saving and emission reduction, and it is an important strategic research direction of vehicle intelligence. A key technical problem of self-driving motorcade is how to design a suitable motorcade controller to operate a vehicle executive mechanism under a current V2V/5G communication mode, so as to follow longitudinal and transverse motion of a head vehicle of the motorcade. The related research work spans interdisciplinary fields such as mechanical engineering, electrical engineering, communications, and control. The foundational theories, technical breakthroughs, and testing and verification at various levels remain incomplete, and there is still a considerable distance to industrial implementation. In particular, in the self-driving motorcade testing technology, there are some problems, such as weak foundation, narrow coverage and low investment, which is an urgent technical problem to be solved.

At present, in the self-driving motorcade testing technology, the two technical routes of real vehicle testing and bench testing are mainly used. The real vehicle testing requires participation of a vehicle under test, opening of communication and control interfaces, and execution of tests at designated testing fields. In comparison, the bench testing does not require a real vehicle platform and can be conducted in a laboratory environment. It offers advantages such as low testing costs, fewer testing procedures, simplicity, safety, reliability, and repeatability, leading to its widespread adoption and application.

The prior art discloses a motorcade simulation system based on virtual reality technology, which uses a driving simulation apparatus to collect head vehicle operation instructions, a VR system to visualize the simulation environment, and a simulation system server to construct the simulation environment and motorcade simulation. The prior art further discloses a driver in-loop intelligent connected vehicle test bench, where a plurality of driving simulation apparatuses are connected to a central server. The driving simulation apparatuses are used to collect driver operation commands, and the central server is used to construct simulation scenarios and motorcade simulations. The above two types of motorcade bench testing systems, developed based on the driving simulation apparatuses, struggle to fully reflect the actual conditions of key motorcade components such as sensing apparatuses, communication apparatuses, control apparatuses, and vehicle propulsion and braking systems during motorcade operation. The prior art further disclose a multi-vehicle pneumatic braking system static test bench, which connects a plurality of pneumatic braking systems to a real-time simulation system for motorcade simulation. This solution is unable to verify the dynamic response characteristics of the vehicle propulsion and braking systems. Additionally, the prior art discloses a CACC stability testing system based on vehicle in-loop, which uses a single vehicle dynamometer test bench to test motorcade CACC stability. This solution can only reflect the real response of one vehicle during conventional CACC testing and is difficult to apply to extreme conditions such as wheel slip.

In summary, the prior art cannot achieve dynamic testing and software-level motorcade integrated scenery, nor can they realize dynamic testing of self-driving motorcades in dynamic scenery scenarios.

### SUMMARY

In view of the above-mentioned problems, it is an objective of the present invention to provide a self-driving motorcade hardware-in-the-loop dynamic testing system and method that integrates “scenery, sensing, communication, control, and execution”, enabling dynamic testing of self-driving motorcades and meeting the demands of complex and extreme operating conditions.

In a first aspect, the present invention provides a self-driving motorcade hardware-in-the-loop dynamic testing system including:
a head vehicle control apparatus configured to provide a head vehicle operation instruction;
a motorcade real-time motion calculation apparatus configured to perform online calculation of the dynamic and kinematic state parameters of a head vehicle and a following vehicle in the self-driving motorcade based on the head vehicle operation instruction; a motorcade scenery apparatus;
a motorcade scenery apparatus configured to acquire the head vehicle operation instruction and the dynamic and kinematic state parameters of the head vehicle and the following vehicle, and display a motorcade operation scene;
a dynamic test bench configured to simulate the actual operation states of the head vehicle and the following vehicle, and test the drive braking operation of the electric drive braking system of each vehicle, where the dynamic test bench includes a head vehicle dynamic test bench and a plurality of following vehicle dynamic test benches; and
a motorcade dynamic test bench loading calculation apparatus configured to dynamically load the electric drive braking system of each vehicle in real-time according to the dynamic and kinematic state parameters of the head vehicle and the following vehicle.

Further, the head vehicle dynamic test bench and the following vehicle i dynamic test bench are of the same structure, and respectively include a vehicle onboard sensor simulation apparatus, a vehicle onboard communication apparatus, a vehicle onboard control apparatus and a vehicle electric drive braking system bench;
the vehicle onboard sensor simulation apparatus is configured to simulate a vehicle onboard positioning sensor characteristic;
the vehicle onboard communication apparatus is configured to enable communication among different vehicles among the motorcades;
the vehicle onboard control apparatus is configured to generate vehicle control commands to control the vehicle electric drive braking system bench to run; and
the vehicle electric drive braking system bench is configured to execute a vehicle drive braking command to perform drive braking operations on the vehicle.

Further, the vehicle onboard sensor simulation apparatus includes a sensor signal simulation module and a sensor module; the sensor signal simulation module is configured to simulate normal and fault characteristics of a global position system (GPS) or Beidou satellite positioning system, and the sensor module is a vehicle onboard positioning sensor configured to receive a signal of the sensor signal simulation module.

Further, the vehicle onboard communication apparatus includes a transmission module and a receiving module, where the transmission module is configured to transmit information such as position of the vehicle to the receiving module of the vehicle onboard communication apparatus of another vehicle; the receiving module is configured to receive position information from the transmission module of another vehicle, and adopt a dedicated short range communication (DSRC) or 5G communication method.

Further, each of the head vehicle dynamic test bench and the following vehicle i dynamic test bench further includes a vehicle electric drive braking system, a bench sensing apparatus, and a dynamometer, the vehicle electric drive braking system is coaxially connected to the dynamometer, and the bench sensing apparatus is mounted at a connecting shaft.

Further, the motorcade dynamic test bench loading calculation apparatus includes a head vehicle dynamic test bench loading calculation module and a following vehicle dynamic test bench loading calculation module, and the head vehicle dynamic test bench loading calculation module and the following vehicle i dynamic test bench loading calculation module respectively use a composite control structure of “feedforward+feedback”, and respectively include:
a lumped disturbance estimation module configured to estimate a dynamometer total disturbance torque;
a feedforward torque calculation module configured to calculate a dynamometer feedforward control torque;
a loading error calculation module configured to calculate a dynamometer rotational speed control error;
a feedback torque calculation module configured to calculate a dynamometer feedback control torque; and
a loading torque calculation module configured to calculate a dynamometer total reference torque.

Further, the motorcade scenery apparatus is implemented by an industrial personal computer, a traffic scene editing module and a traffic scene real-time display module are built in the industrial personal computer, the traffic scene editing module transmits a head vehicle driver operation instruction to the motorcade real-time motion calculation apparatus, and the traffic scene real-time display module acquires vehicle motion state parameters from the motorcade real-time motion calculation apparatus and displays the motorcade operation scene in real-time; where universal serial bus (USB)-to-controller area network (CAN) communication is used for the communication mode between the industrial personal computer and the motorcade real-time motion calculation apparatus.

In a second aspect, the present invention further provides a self-driving motorcade hardware-in-the-loop dynamic testing method including:
initializing and loading a motorcade model for real-time motion calculation;
constructing and displaying a motorcade simulation environment;
giving, by a head vehicle control apparatus, a head vehicle operation instruction;
calculating dynamic and kinematic states of the head vehicle and the following vehicle online;
performing drive braking operations, based on the constructed motorcade dynamic test bench, a vehicle electric drive system by simulating the actual operation state of the head vehicle and the following vehicle; and
dynamically loading, according to the dynamic and kinematic state parameters of the head vehicle and the following vehicle, the vehicle electric drive braking system in real-time.

Further, the performing drive braking operations, based on the constructed motorcade dynamic test bench, a vehicle electric drive system by simulating the actual operation state of the head vehicle and the following vehicle includes:
simulating, by a vehicle onboard controller simulation apparatus, a vehicle onboard positioning sensor dynamic response characteristic;
achieving, according to a given communication topology, motorcade information interaction by a vehicle onboard communication apparatus; and
calculating, by the vehicle onboard controller, a reference torque of the vehicle electric drive braking system in real-time, and performing the drive braking operations on the vehicle in a torque control mode according to the calculated reference torque.

Further, the dynamically loading the electric drive braking system of each vehicle in real-time according to the dynamic and kinematic state parameters of the head vehicle and the following vehicle includes calculating a dynamometer reference torque, and controlling the dynamometer to perform dynamic loading on the vehicle electric drive braking system, specifically as follows:
measuring a dynamometer actual rotational speed and actual torque online;
estimating, using an expanded state observer, a dynamometer system total disturbance torque;
calculating a dynamometer feedforward control reference torque;
calculating a dynamometer rotational speed control error;
calculating a dynamometer feedback control reference torque using a sliding mode control method; and
calculating the dynamometer total reference torque.

With the above technical solution adopted, the present invention has the following advantages:
1. In the present invention, a self-driving motorcade hardware-in-the-loop testing system is designed, which integrates “scenery-sensing-communication-control-execution”. The system can complete the component-level and system-level testing for the networked self-driving motorcade, can realize the dynamic testing and integrated scenery for the self-driving motorcade, and can meet the dynamic testing requirements for complex extreme conditions.
2. The present invention employs a vehicle onboard sensor simulation apparatus that is capable of supporting sensor related testing of the performance of a self-driving motorcade motion control in normal, fault and network attack scenarios.
3. The present invention employs a vehicle drive braking system dynamic test bench that is capable of performing both the motorcade motion control performance testing and the dynamic control performance test.
4. The head vehicle dynamic test bench and the following vehicle dynamic test bench of the present invention respectively include a vehicle onboard sensor simulation apparatus, a vehicle onboard communication apparatus, a vehicle onboard control apparatus and a vehicle electric drive braking system bench, which can respectively verify the characteristics of the sensor, the communication apparatus, the control apparatus and the vehicle electric drive braking system, and the motorcade dynamic test bench loading calculation apparatus provides loading control, which can fully verify the dynamic characteristics of key components of the motorcade.
5. In the present invention, the dynamometer is used to load the drive braking system of the vehicle, which can accurately simulate a dynamic mechanical load of the drive braking system of the vehicle during the antiskid/locking process under the extreme conditions, and effectively expand the testing of the motion performance of the self-driving motorcade under the extreme conditions.

In summary, the present invention can be widely used in self-driving motorcade hardware-in-the-loop test.

### BRIEF DESCRIPTION OF THE DRAWINGS

Various other advantages and benefits will become apparent to a person skilled in the art upon reading the following detailed description of the preferred embodiments. The drawings are only for purposes of illustrating the preferred embodiments and are not to be construed as limiting the present invention. Throughout the drawings, like parts are identified by like reference numerals. In the drawings:

FIG. 1 is a structural diagram showing a self-driving motorcade hardware-in-the-loop dynamic testing system according to an embodiment of the present invention.

FIG. 2 is a structural diagram showing a motorcade real-time motion calculation apparatus according to an embodiment of the present invention.

FIG. 3 is a structural diagram showing a vehicle onboard sensor simulation apparatus according to an embodiment of the present invention.

FIG. 4 is a structural diagram showing a vehicle onboard communication apparatus according to an embodiment of the present invention.

FIG. 5 is a structural diagram showing a motorcade hardware-in-the-loop test bench according to an embodiment of the present invention.

FIG. 6 is a structural diagram showing a motorcade dynamic test bench loading calculation apparatus according to an embodiment of the present invention.

FIG. 7 is a structural diagram showing a head vehicle dynamic test bench loading calculation apparatus according to an embodiment of the present invention.

FIG. 8 is a flow chart of a method for controlling a self-driving motorcade hardware-in-the-loop dynamic testing system according to an embodiment of the present invention.

FIG. 9 is a flow chart of a dynamometer reference torque calculation method for a self-driving motorcade hardware-in-the-loop dynamic testing system according to an embodiment of the present invention.

### DETAILED DESCRIPTION OF THE EMBODIMENTS

It is to be understood that the terminology used herein is for the purpose of describing particular example embodiments only and is not intended to be limiting. Unless the context clearly dictates otherwise, the singular forms “a,” “an,” and “the” used herein may also include plural forms. The terms “comprise,” “include,” “contain,” and “have” are inclusive and thus specify the presence of the stated features, steps, operations, elements, and/or components, but do not preclude the presence or addition of one or more other features, steps, operations, elements, components, and/or combinations thereof. The method steps, processes, and operations described herein are not to be construed as necessarily requiring their execution in a specific order described or illustrated, unless explicitly stated otherwise. It should also be understood that additional or alternative steps may be employed.

Although terms such as first, second, third, etc., may be used herein to describe various elements, components, regions, layers, and/or sections, these elements, components, regions, layers, and/or sections should not be limited by these terms. These terms are used merely to distinguish one element, component, region, layer, or section from another. Unless it is clearly dictated in the context otherwise, terms such as “first,” “second,” and other numerical terms used herein do not imply a sequence or order. Thus, a first element, component, region, layer, or section discussed below may, without departing from the teachings of the exemplary embodiments, be referred to as a second element, component, region, layer, or section.

For ease of description, spatial relative terms such as “inner,” “outer,” “inside,” “outside,” “below,” “above,” etc., may be used herein to describe a relationship of one element or feature to another element or feature as illustrated in the figures. These spatial relative relation terms are intended to encompass different orientations of an apparatus in use or operation beyond those depicted in the figures.

The existing self-driving motorcade bench testing system cannot complete the dynamic testing and software level motorcade integrated scenery, and cannot fully verify the dynamic characteristics of key components of the motorcade. The present invention provides a self-driving motorcade hardware-in-the-loop testing system and method, the method including a head vehicle control apparatus configured to provide a head vehicle operation instruction; a motorcade real-time motion calculation apparatus configured to perform online calculation of the dynamic and kinematic state parameters of a head vehicle and a following vehicle in the self-driving motorcade based on the head vehicle operation instruction; a motorcade scenery apparatus; a motorcade scenery apparatus configured to acquire the head vehicle operation instruction and the dynamic and kinematic state parameters of the head vehicle and the following vehicle, and display a motorcade operation scene; a dynamic test bench configured to simulate the actual operation states of the head vehicle and the following vehicle, and test the drive braking operation of the electric drive braking system of each vehicle, where the dynamic test bench includes a head vehicle dynamic test bench and a plurality of following vehicle dynamic test benches, where the dynamic test bench includes a head vehicle dynamic test bench and a plurality of following vehicle dynamic test benches; and a motorcade dynamic test bench loading calculation apparatus configured to dynamically load the electric drive braking system of each vehicle in real-time according to the dynamic and kinematic state parameters of the head vehicle and the following vehicle. Therefore, the present invention realizes a self-driving motorcade hardware-in-the-loop testing system which integrates “scenery, sensing, communication, control, and execution”, can adapt to the motorcade dynamic testing under complex extreme conditions, and can fully verify the dynamic characteristics of key components of the motorcade.

Hereinafter, exemplary embodiments of the present invention will be described in more detail with reference to the accompanying drawings. While the drawings show exemplary embodiments of the present invention, it should be understood that the present invention may be embodied in various forms and should not be construed as limited to the embodiments set forth herein. Rather, these embodiments are provided so that the disclosure will be thorough and complete, and will fully convey the scope of the present invention to a person skilled in the art.

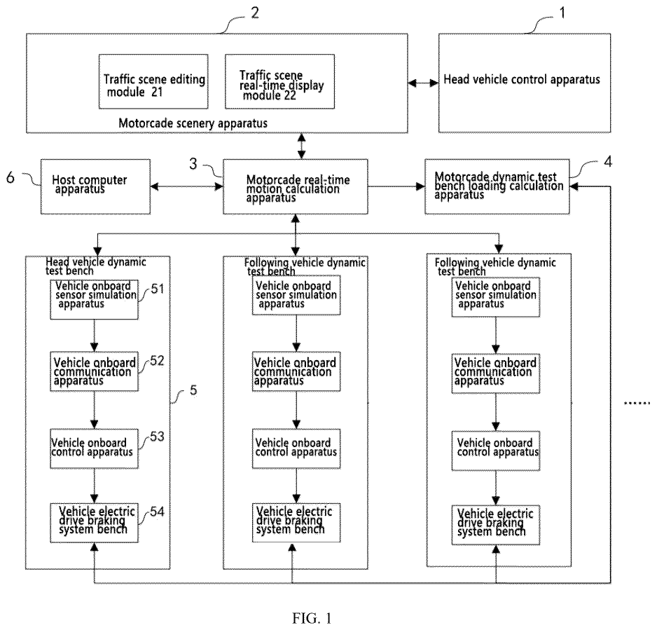

Embodiment 1: as shown in FIG. 1, the present embodiment provides a self-driving motorcade hardware-in-the-loop dynamic testing system, which includes a head vehicle control apparatus 1, a motorcade scenery apparatus 2, a motorcade real-time motion calculation apparatus 3, a dynamic test bench and a motorcade dynamic test bench loading calculation apparatus 4.

The head vehicle control apparatus 1 is configured to provide a head vehicle operation instruction.

A motorcade real-time motion calculation apparatus 3 configured to perform online calculation of the dynamic and kinematic state parameters of a head vehicle and a following vehicle in the self-driving motorcade based on the head vehicle operation instruction; a motorcade scenery apparatus, where a host computer apparatus 6 is further included for initializing the motorcade real-time motion calculation apparatus, monitoring a safety state of the motorcade, and recording dynamic and kinematic data of the vehicle during a test.

The motorcade scenery apparatus 2 is configured to construct and display a simulation dynamic environment, acquire a head vehicle operation instruction and dynamic and kinematic state parameters of a head vehicle and following vehicle, and edit and display a motorcade operation scene in real-time.

The dynamic test bench is configured to simulate the actual operation states of the head vehicle and the following vehicle and perform the drive braking operations on the vehicle, where the dynamic test bench includes a head vehicle dynamic test bench 5 and a number of following vehicle i (i=1, 2, . . . ) dynamic test benches, where the number of the following vehicle dynamic test benches is set according to a length of a motorcade to be tested, and is not limited thereto.

The motorcade dynamic test bench loading calculation apparatus 4 is configured to calculate dynamometer reference torques of the head vehicle dynamic test bench and the following vehicle i dynamic test bench according to the dynamic and kinematic state parameters of the head vehicle and the following vehicle, and is configured to load the motor and simulate the load of the motor during travel of the motorcade. The dynamometer is used to load the drive braking system of the vehicle, which can accurately simulate a dynamic mechanical load of the drive braking system of the vehicle during the antiskid/locking process under the extreme conditions, and effectively expand the testing of the motion performance of the self-driving motorcade under the extreme conditions.

In a preferred embodiment, the motorcade scenery apparatus 2 is implemented by an industrial personal computer, a traffic scene editing module 21 and a traffic scene real-time display module 22 are built in the industrial personal computer, the traffic scene editing module 21 transmits a head vehicle driver operation instruction to the motorcade real-time motion calculation apparatus 3, and the traffic scene real-time display module 22 acquires vehicle motion state parameters from the motorcade real-time motion calculation apparatus 3, and displays the motorcade operation situation in real-time; USB-to-CAN communication is used for the communication mode between the industrial personal computer and the motorcade real-time motion calculation apparatus 3, where the construction and display of the motorcade scenery can be performed by using existing software, which will not be described in detail herein.

In a preferred embodiment, the head vehicle control apparatus 1 has a built-in driver model, and a manned mode or an unmanned mode can be selected and given a head vehicle operation instruction; a USB signal line may be used for the head vehicle control apparatus 1 and an industrial personal computer.

In a preferred embodiment, as shown in FIG. 1, the head vehicle dynamic test bench 5 and the following vehicle i dynamic test bench are of the same structure, and the present embodiment is illustrated by taking the head vehicle dynamic test bench 5 as an example, where the head vehicle dynamic test bench 5 includes a vehicle onboard sensor simulation apparatus 51, a vehicle onboard communication apparatus 52, a vehicle onboard control apparatus 53 and a vehicle electric drive braking system bench 54;
the vehicle onboard sensor simulation apparatus 51 is configured to simulate a vehicle onboard positioning sensor characteristic;
the vehicle onboard communication apparatus 52 is configured to complete communication among different vehicles among the motorcades;
the vehicle onboard control apparatus 53 is configured to generate vehicle control commands to control the vehicle electric drive braking system bench to run; and
the vehicle electric drive braking system bench 54 is configured to execute a vehicle drive braking command to perform drive braking operations on the vehicle.

Further, as shown in FIG. 3, the vehicle onboard sensor simulation apparatus 51 includes a sensor signal simulation module 511 and a sensor module 512; the sensor signal simulation module 511 is configured to simulate the normal and fault characteristics of the GPS or Beidou satellite positioning system, including the characteristics of delay, noise, fault and network attack. The sensor module 512 is a vehicle onboard positioning sensor for receiving a signal from the sensor signal simulation module 511.

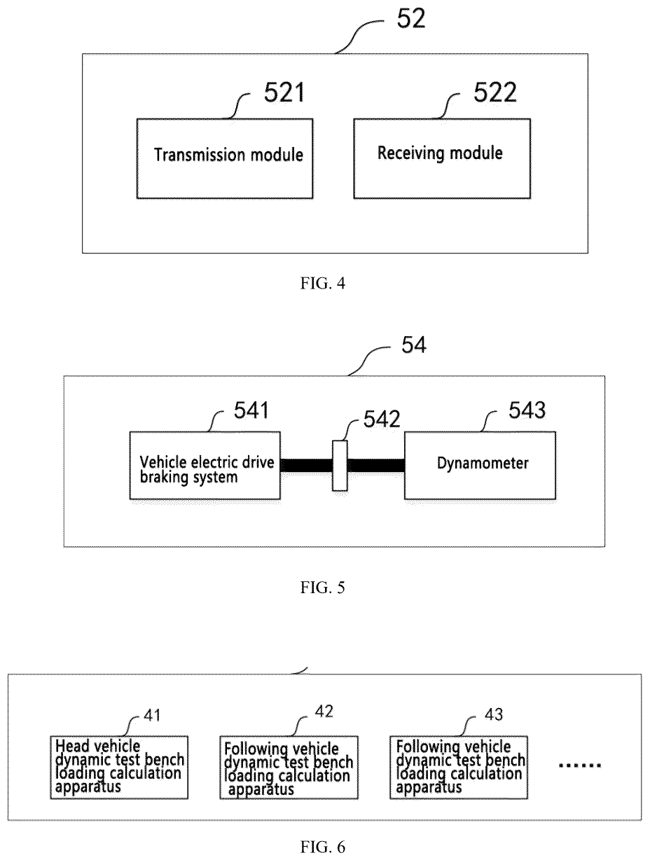

Further, as shown in FIG. 4, the vehicle onboard communication apparatus 52 includes a transmission module 521 and a receiving module 522, where the transmission module 521 is mainly configured to transmit information such as a position of a current vehicle to the receiving module of the vehicle onboard communication apparatus of another vehicle; the receiving module 522 is mainly configured to receive position information and the like from the transmission module of another vehicle, and adopt DSRC or 5G communication mode.

Further, as shown in FIG. 5, both the head vehicle dynamic test bench 5 and the following vehicle i dynamic test bench further include a vehicle electric drive braking system 541, a bench sensing apparatus 542 and a dynamometer 543, where the vehicle electric drive braking system 541 is coaxially connected to the dynamometer 543, and the bench sensing apparatus 542 is mounted at the connecting shaft; the vehicle electric drive braking system 541 can be a pure electric drive braking system, a hybrid power system, a hydrogen energy engine system, etc. and the dynamometer 543 simulates a road load in real-time, where the vehicle electric drive braking system 541 is a real power system of a vehicle in a motorcade to be tested and is a component to be tested; the bench sensing apparatus 542 is configured to measure the rotational speed and torque information about the bench; the dynamometer 543 is used to dynamically load the vehicle electric drive braking system in real-time according to a motorcade operation condition.

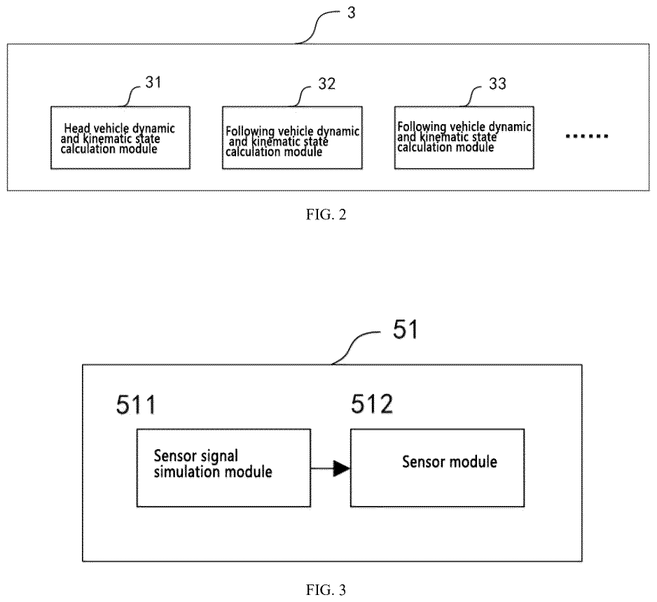

In a preferred embodiment, as shown in FIG. 2, the motorcade real-time motion calculation apparatus 3 includes a head vehicle dynamic and kinematic state calculation module 31, and following vehicle i dynamic and kinematic state calculation modules 32, 33, . . . , where the above-mentioned calculation modules have built-in vehicle dynamics models and kinematics models, where the number of following vehicle i dynamic and kinematic state calculation modules is set according to a length of the motorcade to be tested; the head vehicle dynamic and kinematic state calculation module 31 and the following vehicle i dynamic and kinematic state calculation modules 32, 33, . . . , by integrating the head vehicle operation instruction, the actual operation states of the head vehicle dynamic test bench and the following vehicle i dynamic test bench, the dynamic and kinematic states of the head vehicle and the following vehicle i are calculated, including the data such as the acceleration, speed and position of the vehicle, which are transmitted to the head vehicle dynamic test bench 5, the following vehicle i dynamic test bench and the motorcade dynamic test bench loading calculation apparatus 4.

In a preferred embodiment, as shown in FIG. 6, the motorcade dynamic test bench loading calculation apparatus 4 includes a head vehicle dynamic test bench loading calculation module 41 and following vehicle i dynamic test bench loading calculation modules 42, 43, . . . which respectively calculate dynamometer reference torques of the head vehicle dynamic test bench 5 and following vehicle i dynamic test bench using a speed-controlled load simulation method; the number of the following vehicle i (i=1, 2.) dynamic test bench loading calculation modules is set according to a length of ag motorcade to be tested.

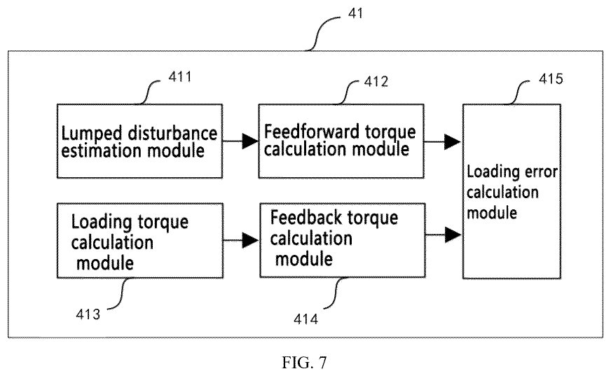

Further, as shown in FIG. 7, both the head vehicle dynamic test bench loading calculation module 41 and the following vehicle i dynamic test bench loading calculation modules 42, 43, . . . adopt a composite control structure of “feedforward+feedback”, and the head vehicle dynamic test bench loading calculation module 41 is explained, including a lumped disturbance estimation module 411, a feedforward torque calculation module 412, a loading error calculation module 413, a feedback torque calculation module 414 and a loading torque calculation module 415;
the lumped disturbance estimation module 411 is configured to estimate a dynamometer total disturbance torque;
the feedforward torque calculation module 412 is configured to calculate a dynamometer feedforward control torque;
the loading error calculation module 413 is configured to calculate a dynamometer rotational speed control error;
the feedback torque calculation module 414 is configured to calculate a dynamometer feedback control torque; and
the loading torque calculation module 415 is configured to calculate a dynamometer total reference torque.

In a preferred embodiment, CAN communication is used among the motorcade real-time motion calculation apparatus 3, the head vehicle dynamic test bench 5, the following vehicle i dynamic test bench and the motorcade dynamic test bench loading calculation apparatus.

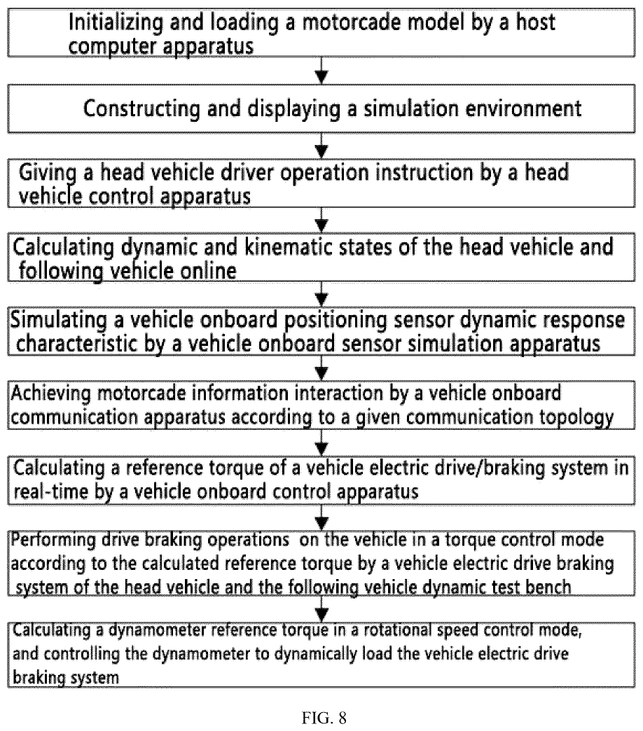

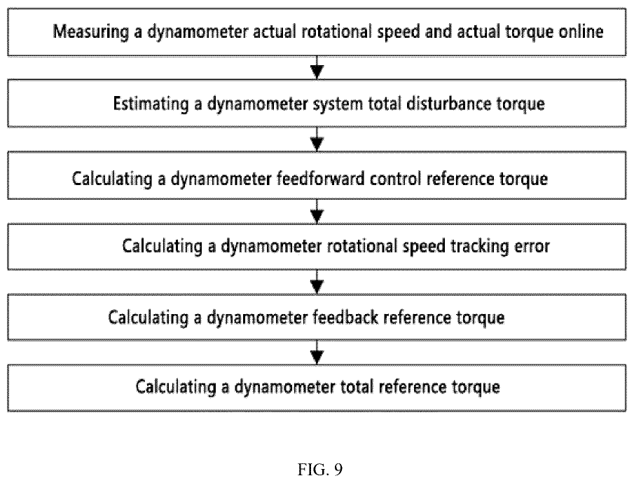

Embodiment 2: as shown in FIG. 8, the present embodiment provides a method for controlling a self-driving motorcade hardware-in-the-loop dynamic testing system, which includes the steps of:
S1: initializing is performed, and a motorcade model is loaded by a host computer apparatus 6 for real-time motion calculation;
S2: a simulation environment is constructed and a motorcade scenery apparatus 3 is displayed in an industrial personal computer;
S3: a head vehicle operation instruction is given by a head vehicle operation apparatus 1;
S4: the dynamic and kinematic states of the head vehicle and the following vehicle are calculated online;
S5: the performing online calculation of the dynamic and kinematic state parameters of a head vehicle and a following vehicle in the self-driving motorcade based on the head vehicle operation instruction includes:
S51: the vehicle onboard sensor 51 simulates the dynamic response the vehicle onboard positioning sensor characteristic;
S52: motorcade information interaction is achieved by a vehicle onboard communication apparatus 52 according to a given communication topology;
S53: the vehicle onboard control apparatus 53 calculates a reference torque of the vehicle electric drive braking system in real-time;
S54: it is determined that the vehicle electric drive braking system adopts the torque control mode;
S55: the vehicle is performed drive braking operation according to the calculated reference torque;
S6: as shown in FIG. 9, the dynamically loading the electric drive braking system of each vehicle in real-time according to the dynamic and kinematic state parameters of the head vehicle and the following vehicle includes calculating a dynamometer reference torque in a rotational speed control mode, and controlling the dynamometer to perform dynamic loading on the vehicle electric drive braking system, specifically as follows:
S61: a dynamometer actual rotational speed and actual torque online are measured;
S62: a dynamometer system total disturbance torque is estimated using an expanded state observer;
S63: a dynamometer feedforward control reference torque is calculated;
S64: the dynamometer rotational speed control error is calculated;
S65: a dynamometer feedback control reference torque is calculated using a sliding mode control method; and
S66: the dynamometer total reference torque is calculated.

Various embodiments in this description are described in a progressive manner, and identical or similar parts among the embodiments can be referred to each other. Each embodiment focuses on explaining the differences from other embodiments. In the description of the description, reference to terms such as ‘one embodiment’ or ‘some implementations’ means that the specific features, structures, materials, or characteristics described in connection with the embodiment or example are included in at least one embodiment or example of the embodiments of the description. In this description, schematic representations of the above terms are not necessarily directed to the same embodiment or example. In addition, the particular features, structures, materials, or characteristics described may be combined in any one or more embodiments or examples in a suitable manner. Moreover, various embodiments or examples described in the description, as well as features of various embodiments or examples, may be integrated and combined by a person skilled in the art without departing from the scope of the present disclosure.

Finally, it should be noted that: the above embodiments are only used to illustrate the technical solution of the present invention, and not to limit the same; while the present invention has been described in detail and with reference to the foregoing embodiments, it will be understood by a person skilled in the art that: the technical solutions described in the foregoing embodiments may still be modified, or some technical features may be equivalently replaced; and these modifications or substitutions do not depart from the spirit and scope of the corresponding technical solutions of the embodiments of the present invention.

What is claimed is:

1. A hardware-in-the-loop dynamic testing system for a self-driving motorcade, comprising:
a head vehicle control apparatus, configured to provide a head vehicle operation instruction;
a motorcade real-time motion calculation apparatus, configured to perform online calculation of dynamic and kinematic state parameters of a head vehicle and a following vehicle in the self-driving motorcade based on the head vehicle operation instruction;
a motorcade scenery apparatus, configured to acquire the head vehicle operation instruction and the dynamic and kinematic state parameters of the head vehicle and the following vehicle, and display a motorcade operation scene;
a dynamic test bench, configured to simulate actual operation states of the head vehicle and the following vehicle, and test a drive braking operation of an electric drive braking system of each vehicle, wherein the dynamic test bench comprises a head vehicle dynamic test bench and a plurality of following vehicle dynamic test benches; and
a motorcade dynamic test bench loading calculation apparatus, configured to dynamically load the electric drive braking system of each vehicle in real-time according to the dynamic and kinematic state parameters of the head vehicle and the following vehicle.

2. The hardware-in-the-loop dynamic testing system for the self-driving motorcade according to claim 1, wherein the head vehicle dynamic test bench and the following vehicle dynamic test bench are of a same structure, and respectively comprise a vehicle onboard sensor simulation apparatus, a vehicle onboard communication apparatus, a vehicle onboard control apparatus and a vehicle electric drive braking system bench;
the vehicle onboard sensor simulation apparatus is configured to simulate a vehicle onboard positioning sensor characteristic;
the vehicle onboard communication apparatus is configured to enable communication among different vehicles among motorcades;
the vehicle onboard control apparatus is configured to generate vehicle control commands to control the vehicle electric drive braking system bench to run; and
the vehicle electric drive braking system bench is configured to execute a vehicle drive braking command to perform drive braking operations on the vehicle.

3. The hardware-in-the-loop dynamic testing system for the self-driving motorcade according to claim 2, wherein the vehicle onboard sensor simulation apparatus comprises a sensor signal simulation module and a sensor module; the sensor signal simulation module is configured to simulate normal and fault characteristics of a global position system (GPS) or Beidou satellite positioning system, and the sensor module is a vehicle onboard positioning sensor configured to receive a signal of the sensor signal simulation module.

4. The hardware-in-the-loop dynamic testing system for the self-driving motorcade according to claim 2, wherein the vehicle onboard communication apparatus comprises a transmission module and a receiving module, wherein the transmission module is configured to transmit information comprising position of the vehicle to the receiving module of the vehicle onboard communication apparatus of another vehicle; the receiving module is configured to receive position information from the transmission module of another vehicle, and adopt a dedicated short range communication (DSRC) or 5G communication method.

5. The hardware-in-the-loop dynamic testing system for the self-driving motorcade according to claim 1, wherein the head vehicle dynamic test bench and the following vehicle dynamic test bench respectively further comprise a vehicle electric drive braking system, a bench sensing apparatus, and a dynamometer, wherein the vehicle electric drive braking system is coaxially connected to the dynamometer, and the bench sensing apparatus is mounted at a connecting shaft.

6. The hardware-in-the-loop dynamic testing system for the self-driving motorcade according to claim 1, wherein the motorcade dynamic test bench loading calculation apparatus comprises a head vehicle dynamic test bench loading calculation module and a following vehicle dynamic test bench loading calculation module, and the head vehicle dynamic test bench loading calculation module and the following vehicle dynamic test bench loading calculation module respectively use a composite control structure of “feedforward+feedback”, respectively comprising:
a lumped disturbance estimation module configured to estimate a dynamometer total disturbance torque;
a feedforward torque calculation module configured to calculate a dynamometer feedforward control torque;
a loading error calculation module configured to calculate a dynamometer rotational speed control error;
a feedback torque calculation module configured to calculate a dynamometer feedback control torque; and
a loading torque calculation module configured to calculate a dynamometer total reference torque.

7. The hardware-in-the-loop dynamic testing system for the self-driving motorcade according to claim 1, wherein the motorcade scenery apparatus is implemented by an industrial personal computer, a traffic scene editing module and a traffic scene real-time display module are built in the industrial personal computer, the traffic scene editing module transmits a head vehicle driver operation instruction to the motorcade real-time motion calculation apparatus, and the traffic scene real-time display module acquires vehicle motion state parameters from the motorcade real-time motion calculation apparatus and displays the motorcade operation scene in real-time; wherein universal serial bus (USB)-to-controller area network (CAN) communication is used for a communication mode between the industrial personal computer and the motorcade real-time motion calculation apparatus.

8. A hardware-in-the-loop dynamic testing method of a self-driving motorcade, comprising:
initializing and loading a motorcade model for real-time motion calculation;
constructing and displaying a motorcade simulation environment;
giving a head vehicle operation instruction by a head vehicle control apparatus;
calculating dynamic and kinematic states of head vehicle and a following vehicle online;
performing drive braking operations on a vehicle electric drive system by simulating an actual operation state of the head vehicle and the following vehicle based on a constructed motorcade dynamic test bench; and
dynamically loading a vehicle electric drive braking system in real-time, according to the dynamic and kinematic state parameters of the head vehicle and the following vehicle.

9. The hardware-in-the-loop dynamic testing method according to claim 8, wherein the step of performing drive braking operations on the vehicle electric drive system by simulating the actual operation state of the head vehicle and the following vehicle based on the constructed motorcade dynamic test bench comprises:
simulating a vehicle onboard positioning sensor dynamic response characteristic by a vehicle onboard controller simulation apparatus;
achieving motorcade information interaction by a vehicle onboard communication apparatus according to a given communication topology; and
calculating a reference torque of the vehicle electric drive braking system in real-time by a vehicle onboard controller, and performing the drive braking operations on the vehicle in a torque control mode according to the reference torque.

10. The hardware-in-the-loop dynamic testing method according to claim 8, wherein the step of dynamically loading the electric drive braking system of each vehicle in real-time according to the dynamic and kinematic state parameters of the head vehicle and the following vehicle comprises calculating a dynamometer reference torque, and controlling a dynamometer to perform dynamic loading on the vehicle electric drive braking system, comprising:
measuring a dynamometer actual rotational speed and actual torque online;
estimating a dynamometer system total disturbance torque using an expanded state observer;
calculating a dynamometer feedforward control reference torque;
calculating a dynamometer rotational speed control error;
calculating a dynamometer feedback control reference torque using a sliding mode control method; and
calculating a dynamometer total reference torque.
